(19) United States
(12) Patent Application Publication
(10) Pub. No.: US 2007/0290296 A1
(43) Pub. Date: Dec. 20, 2007

(54) Fuse Structures and Methods of Forming the Same

(75) Inventor: Chear-Yeon Mun, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/745,493

(22) Filed: May 8, 2007

(30) Foreign Application Priority Data
Jun. 20, 2006 (KR) 2006-55167

(51) Int. Cl. H01L 29/00; H01L 21/326

(52) U.S. Cl. 257/529; 438/467; 257/E23.149

(57) ABSTRACT

A fuse structure includes an insulating structure, a fuse pattern, an insulating pattern and an insulating layer. The insulating structure has a fuse region and a wire region proximate the fuse region. The fuse pattern is on the fuse region. The insulating pattern has a first portion and a second portion. The first portion is located on the fuse region and covers a sidewall of the fuse pattern. The second portion is located on the wire region. The insulating layer is on the insulating pattern and the fuse pattern and has a height selected to limit spread of fractures of the fuse pattern generated by cutting of the fuse pattern.

### CROSS-REFERENCE TO RELATED APPLICATION

This application is related to and claims priority under 35 USC § 119 from Korean Patent Application No. 10-2006-0055167, filed on Jun. 20, 2006 in the Korean Intellectual Property Office, the disclosure of which is incorporated herein by reference in its entirety.

### BACKGROUND OF THE INVENTION

The present invention relates to fuse structures and methods of forming the fuse structures. More particularly, the present invention relates to fuse structures used to cut off a current and methods of forming the same.

Conventional fuse structures generally include fuse patterns, each of which has a substantially bar shape. Generally, upper faces of the fuse patterns are exposed. As a result, when laser beams are irradiated onto the fuse patterns, the fuse patterns may be overheated. As a result, the fuse patterns may be burned (cut) to disconnect the current flow path through the conventional fuse patterns.

FIG. 1 is a scanning electron microscope (SEM) picture showing a conventional fuse structure having a fuse pattern that is cut. As shown in FIG. 1, a laser beam has been irradiated onto a target region of the fuse pattern so that the fuse pattern may be cut. In this case, fractures (portions of conductive material after irradiation) of the target region may be spattered widely so that a fracture may be attached and electrically connected to the remaining portion of the fuse pattern. In addition, the fracture may be attached and electrically connected to a wire pattern adjacent to the fuse pattern. As a result, the fracture may generate an electric short between the wire and fuse patterns.

### SUMMARY OF THE INVENTION

Some embodiments of the present invention include a fuse structure including an insulating structure, a fuse pattern, an insulating pattern and an insulating layer. The insulating structure has a fuse region and a wire region proximate the fuse region. The fuse pattern is on the fuse region. The insulating pattern has a first portion and a second portion. The first portion is located on the fuse region and covers a sidewall of the fuse pattern. The second portion is located on the wire region. The insulating layer is on the insulating pattern and the fuse pattern and has a height selected to limit spread of fractures of the fuse pattern generated by cutting of the fuse pattern.

In other embodiments, the fuse structure includes a first wire pattern on the wire region. The first wire pattern has a sidewall covered by the second portion. A second wire pattern is on the second portion that is electrically connected to the first wire pattern. The insulating layer is on exposed surfaces of the insulating pattern, the fuse pattern and the second wire pattern. A height of the first portion may be less than a height of the second portion. A height of the fuse pattern may be less than a height of the first wire pattern. A ratio of the height of the fuse pattern to the height of the first wire pattern may be about 1:7 to about 1:4. The insulating layer may include silicon oxide and the fuse pattern may include aluminum. A ratio of the height of the insulating layer to the height of the fuse pattern may be about 3:7 to about 5:6. The insulating layer may include at least two insulating films.

In further embodiments, methods of forming a fuse structure are provided. A preliminary conductive pattern is formed on an insulating structure. A first insulating layer is formed on the insulating structure and covering the preliminary conductive pattern. Heights of the first insulating layer and the preliminary conductive pattern are reduced to form a fuse pattern and a first insulating pattern. A sidewall of the fuse pattern is covered by the first insulating pattern. A second insulating layer is formed on the first insulating pattern and the fuse pattern. The further insulating layer is formed to a height selected to limit spread of fractures of the fuse pattern generated by cutting of the fuse pattern.

In other embodiments, reducing heights of the first insulating layer and the preliminary conductive pattern includes etching the first insulating layer and the preliminary conductive pattern to form a preliminary first insulating pattern and a conductive pattern. The preliminary first insulating pattern has a height less than a height of the first insulating layer. The conductive pattern has a height less than the height of the preliminary conductive pattern. The conductive pattern has a sidewall covered by the preliminary first insulating pattern. A conductive layer is formed on the preliminary first insulating pattern and the conductive pattern. The conductive layer, the preliminary first insulating pattern and the conductive pattern are etched to form the first insulating pattern and the fuse pattern. The first insulating pattern has a height less than the height of the preliminary pattern. The fuse pattern has a height less than the height of the conductive pattern and a sidewall covered by the first insulating pattern.

In further embodiments, reducing heights of the first insulating layer and the preliminary conductive pattern includes reducing heights of the first insulating layer and the preliminary conductive pattern to provide a ratio of the height of the fuse pattern to the height of the first wire pattern of about 1:7 to about 1:4. The preliminary conductive pattern may include aluminum and the insulating layer may include silicon oxide. Forming the second insulating layer may include forming the height of the insulating layer to provide a ratio of the height of the insulating layer to the height of the fuse pattern of about 3:7 to about 5:6. Forming the second insulating layer may include forming a first insulating film and forming a second insulating film on the first insulating film. The first insulating film may be a silicon oxide film and the second insulating film may be a silicon nitride film.

In yet further embodiments, forming a preliminary conductive pattern includes forming a first adhesive layer and forming a first capping layer on the first adhesive layer. A conductive layer is formed on the first capping layer. A second adhesive layer is formed on the conductive layer and a second capping layer is formed on the second adhesive layer. A mask pattern is formed on the second capping layer. The first adhesive layer, the first capping layer, the conductive layer on the first capping layer, the second adhesive layer and the second capping layer are etched using the mask pattern to form the preliminary conductive pattern. The first and second adhesive layer may include a metal and the first and second capping layer may include a metal nitride.

In other embodiments, methods of forming a fuse structure include providing an insulating structure including a wire region and a fuse region. A first wire pattern is formed on the wire region. A preliminary conductive pattern is formed on the fuse region. A first insulating layer is formed on the insulating structure that covers the first wire pattern and the preliminary conductive pattern. The first insulating layer and the preliminary conductive pattern are etched to form a preliminary first insulating pattern and a conductive pattern. The preliminary first insulating pattern has an opening exposing a portion of the first wire pattern. The preliminary first insulating pattern includes a first portion located on the wire region and a second portion located on the fuse region. The second portion has a height less than a height of the first portion. The conductive pattern has a height less than a height of the preliminary conductive pattern. A conductive layer is formed on the preliminary first insulating pattern, the first wire pattern and the conductive pattern. The conductive layer fills the opening exposing the portion of the first wire pattern. The conductive layer, the preliminary conductive pattern and the preliminary first insulating pattern are etched to form a second wire pattern, a fuse pattern and a first insulating pattern. The second wire pattern is located on the second portion and electrically connected to the first wire pattern. The fuse pattern has a height less than a height of the preliminary conductive pattern. A portion of the first insulating pattern located on the fuse region has a height less than the height of the first portion. An insulating layer is formed on the etched conductive layer, the preliminary conductive pattern and the preliminary first insulating pattern to a height selected to limit spread of fractures of the fuse pattern generated by cutting of the fuse pattern.

In further embodiments, etching the first insulating layer is preceded by forming a mask pattern on the first insulating layer. The mask pattern includes a first opening on the fuse region and a second opening on the wire region. The first opening has a width greater than a width of the second opening to provide a greater etch rate in the fuse region than the wire region. The first insulating layer and the preliminary conductive pattern are etched using the mask pattern.

In yet other embodiments, a ratio of the height of the fuse pattern to the height of the first wire pattern is about 1:7 to about 1:4. Forming the insulating layer may include forming the insulating layer to provide a ratio of the height of the insulating layer to the height of the fuse pattern of about 3:7 to about 5:6.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a scanning electron microscope (SEM) picture showing a conventional fuse structure having a fuse pattern that is cut;

FIG. 2 is a cross-sectional view illustrating a fuse structure in accordance with some embodiments of the present invention;

FIGS. 3 to 9 are cross-sectional views illustrating a method of forming the fuse structure shown in FIG. 2;

FIG. 10 is a cross-sectional view illustrating a fuse structure in accordance with further embodiments of the present invention; and

FIGS. 11 to 17 are cross-sectional views illustrating a method of forming the fuse structure shown in FIG. 10.

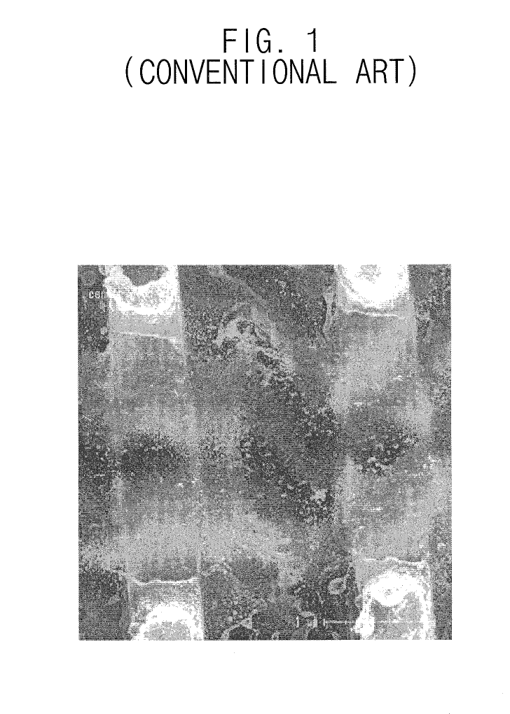

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

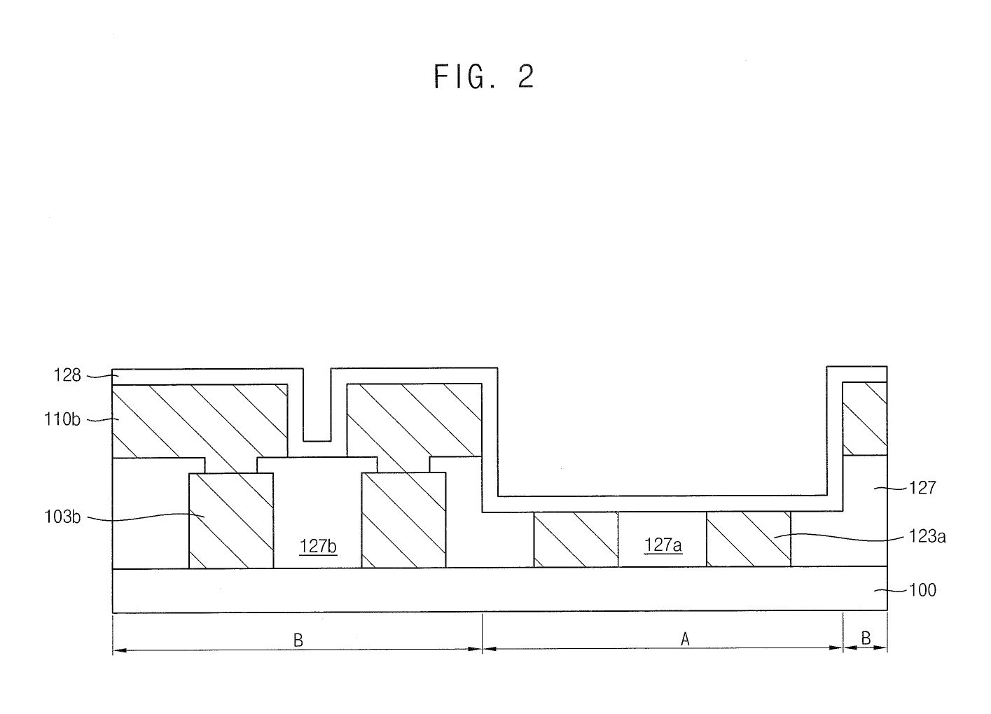

FIG. 2 is a cross-sectional view illustrating a fuse structure in accordance with some embodiments of the present invention. Referring to FIG. 2, a fuse structure 1000 includes an insulating structure 100, a fuse pattern 123a, a first wire pattern 103b, a first insulating pattern 127, a second wire pattern 110b and a second insulating layer 128.

The insulating structure 100 has a fuse region A and a wire region B. The insulating structure 100 may be an oxide, such as silicon oxide. In some embodiments, the insulating structure 100 may be a nitride, such as silicon nitride.

Although not illustrated in FIG. 2, a contact electrically connected to a conductive structure that is located below the insulating structure 100 may be formed through the insulating structure 100. The underlying conductive structure may be, for example, part of a transistor, a capacitor, a wire pattern and/or a word line, a bit line, a source region and/or a drain region.

The fuse pattern 123a and the first wire pattern 103b are located on the fuse region A and the wire region B, respectively. The fuse pattern 123a and/or the wire pattern 103b may include a metal, such as aluminum. The fuse pattern 123a and/or the wire pattern 103b may include polysilicon doped with impurities.

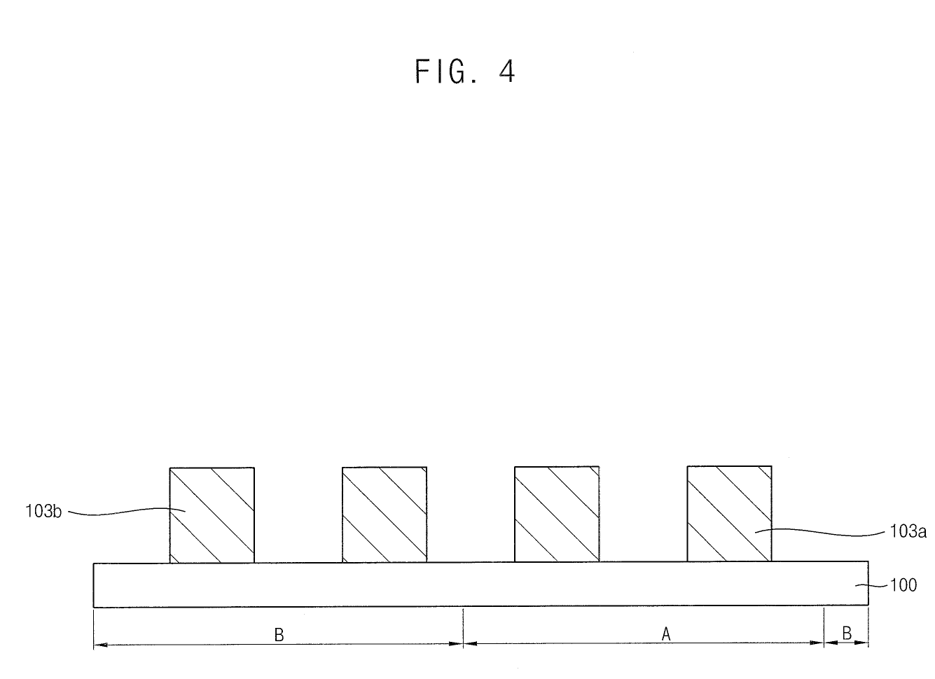

A height of the fuse pattern 123a may be substantially less than a height of a structure 103a formed with the first wire pattern 103b (as shown in FIG. 4). When a ratio of the height of the fuse pattern 123a to the height of the first wire pattern 103b is less than about 1:7, an intensity of a laser beam required to cut the fuse pattern 123a may be relatively large. In addition, the amount of by-product generated when the fuse pattern 123a is cut may be relatively large. On the other hand, when the ratio of the height of the fuse pattern 123a to the height of the first wire pattern 103b is greater than about 1:4, etching processes required to form the fuse pattern 123a may damage the first insulating pattern 127 excessively. Thus, the ratio of the height of the fuse pattern 123a to the height of the first wire pattern 103b may be about 1:7 to about 1:4 in some embodiments. For example, in some embodiments, the height of the first wire pattern 103b is about 100 Å and the height of the fuse pattern 123a is about 40 Å to about 70 Å.

The first insulating pattern 127 may be formed on the insulating structure 100 to enclose sidewalls of the first wire pattern 103b and the fuse pattern 123a. The first insulating pattern 127 may be an oxide, such as silicon oxide. The first insulating pattern 127 may be a nitride, such as silicon nitride.

The first insulating pattern 127 shown in FIG. 2 includes a first portion 127a and a second portion 127b located on the fuse region A and the wire region B, respectively. A height of the first portion 127a may be less than a height of the second portion 127b.

The second wire pattern 110b is located on the second portion 127b of the first insulating pattern 127. In addition, the second wire pattern 110b is electrically connected to the first wire pattern 103b. For the embodiments illustrated in FIG. 2, the second wire pattern 110b is not formed over the fuse region A. The second wire pattern 110b may include a metal, such as aluminum and/or a polysilicon doped with impurities.

The second insulating layer 128 is formed on the second wire pattern 110b, the first insulating pattern 127 and the fuse pattern 123a. The second insulating layer 128 may include be oxide, such as silicon oxide. In some embodiments, the second insulating layer 128 may be a nitride, such as silicon nitride. The second insulating layer 128 may include two or more insulating films. For example, the second insulating layer 128 may include a silicon oxide film and a silicon nitride film formed on the silicon oxide film.

When a ratio of a height of the second insulating layer 128 to the height of the fuse pattern 123a is less than about 3:7, the second insulating layer 128 may not be fully protective. In this case, fractures of the fuse pattern 123a may spatter widely when the laser beam cuts the fuse pattern 123a. When the ratio of the height of the second insulating layer 128 to the height of the fuse pattern 123a is greater than about 5:6, the intensity of the laser beam required to cut the fuse pattern 123a may be relatively large. Thus, the ratio of the height of the second insulating layer 128 to the height of the fuse pattern 123a in some embodiments is from about 3:7 to about 5:6. In some embodiments, the height of the fuse pattern 123a is about 70 Å and the height of the second insulating layer 128 is about 50 Å. In further embodiments, the height of the fuse pattern 123a is about 70 Å and the height of the second insulating layer 128 is about 30 Å.

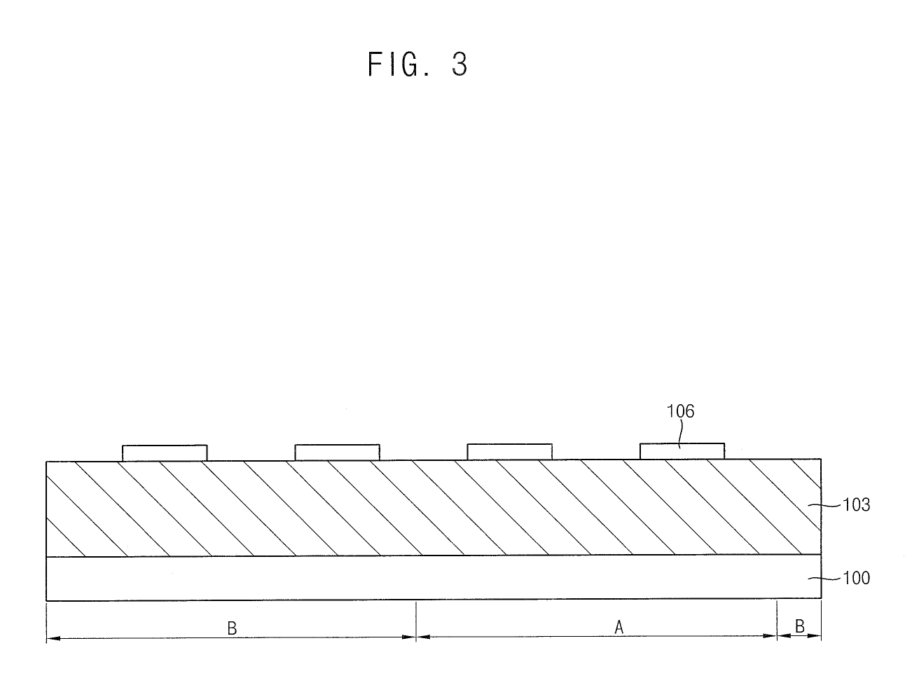

FIGS. 3 to 9 are cross-sectional views illustrating a method of forming the fuse stricture shown in FIG. 2. Referring first to FIG. 3, an insulating stricture 100 having a fuse region A and a wire region B is formed. The insulating structure 100 may be an oxide, such as silicon oxide and/or a nitride, such as silicon nitride. Although not illustrated in FIG. 3, a contact electrically connected to a conductive structure located below the insulating structure 100 may be formed through the insulating structure 100. The underlying conductive structure may be a transistor, a capacitor, a wire pattern, a word line, a bit line, a source region or a drain region.

A first conductive layer 103 is formed on the insulating structure 100. The first conductive layer 103 may include a metal, such as aluminum and/or a polysilicon doped with impurities.

A first mask pattern 106 is formed on the first conductive layer 103. The first mask pattern 106 and the first conductive layer 103 may include substantially different materials to achieve an etching selectivity. The first mask pattern may include a nitride, such as silicon nitride and/or an oxide, such as silicon oxide.

Referring now to FIG. 4, a first etching process is performed on the first conductive layer 103. The first mask pattern 106 is used as an etch mask in the first etching process. Thus, the first conductive layer 103 may be transformed into a preliminary conductive pattern 103a and the first wire pattern 103b. The preliminary conductive pattern 103a and the first wire pattern 103b may be formed on the fuse region A and the wire region B, respectively.

The first mask pattern 106 is then removed. For example, the first mask pattern 106 may be removed by an ashing process and/or a strip process. In other words, these processes may be used alone or in combination.

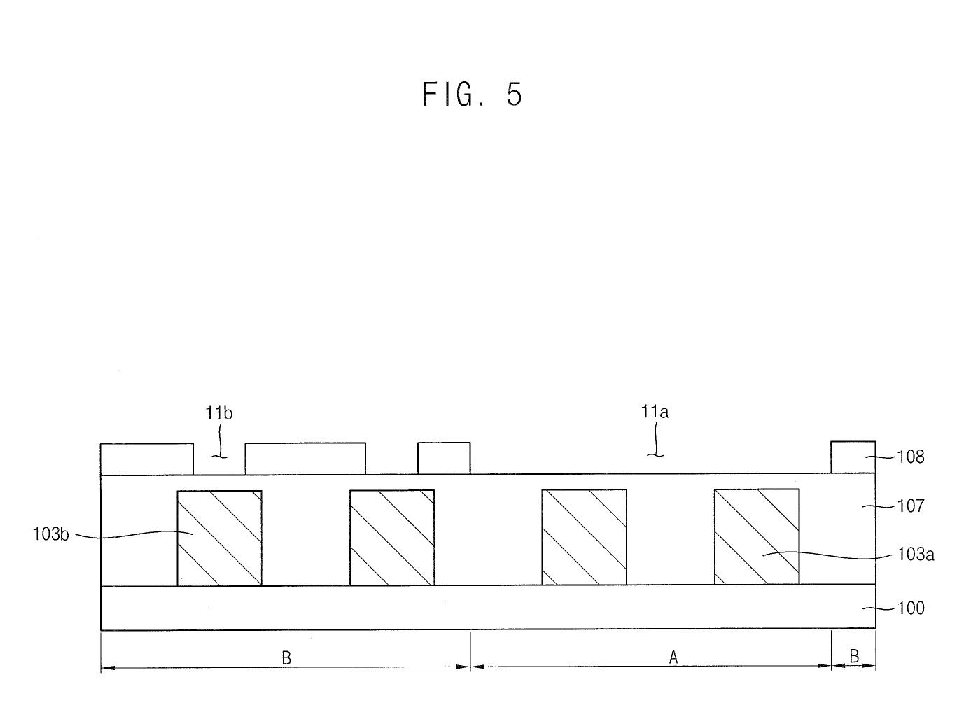

Referring to FIG. 5, a first insulating layer 107 is formed on the insulating structure 100 that covers the preliminary conductive pattern 103a and the first wire pattern 103b. The first insulating layer 107 may include an oxide, such as silicon oxide and/or a nitride, such as silicon nitride.

A second mask pattern 108 is formed on the first insulating layer 107. The second mask pattern 108 has a first hole 11a and a second hole 11b. The first hole 11a corresponds to the fuse region A and the second hole 11b corresponds to a first wire pattern 103b located on the wire region B. In the embodiments of FIG. 5, a width of the first hole 11a is substantially greater than a width of the second hole 11b.

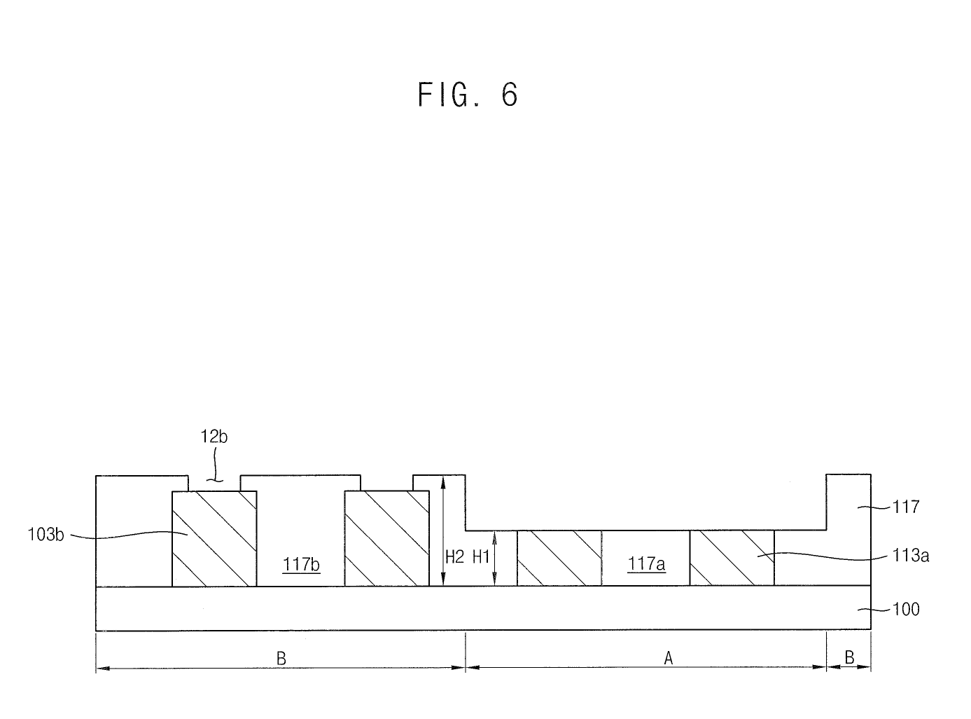

Referring to FIG. 6, a second etching process is performed on the first insulating layer 107 and the preliminary conductive pattern 103a using the second mask pattern 108 as an etch mask. As described above, the width of the first hole 11a is substantially greater than the width of the second hole 11b. Thus, the amount of an etchant provided through the second hole 11b may be substantially less than the amount of the etchant provided through the first hole 11a. In addition, the amount of by-product removed through the second hole 11b may be substantially less than the amount of by-product removed through the first hole 11a. Thus, an etch rate measured under the second hole 11b may be substantially less than an etch rate measured under the first hole 11a.

The first insulating layer 107 may be formed into a preliminary first insulating pattern 117 by the second etching process. The preliminary first insulating pattern 117 may include a first portion 117a and a second portion 117b located on the fuse region A and the wire region B, respectively. The first portion 117a and the second portion 117b may have a first height H1 and a second height H2, respectively. The first height H1, in the illustrated embodiments of FIG. 6, is substantially less than the second height H2.

The second portion 117b of the preliminary first insulating pattern 117 has an opening 12b partially exposing the first wire pattern 103b. A thin layer of the portion of the first wire pattern 103b exposed through the opening 12b may be removed by the second etching process.

The preliminary conductive pattern 103a is formed into a conductive pattern 113a having a height substantially less than that of the preliminary conductive pattern 103a. The first portion 117a of the preliminary first insulating pattern 117 encloses (covers) a sidewall of the conductive pattern 113a. Thus, an upper face of the conductive pattern 113a may be exposed.

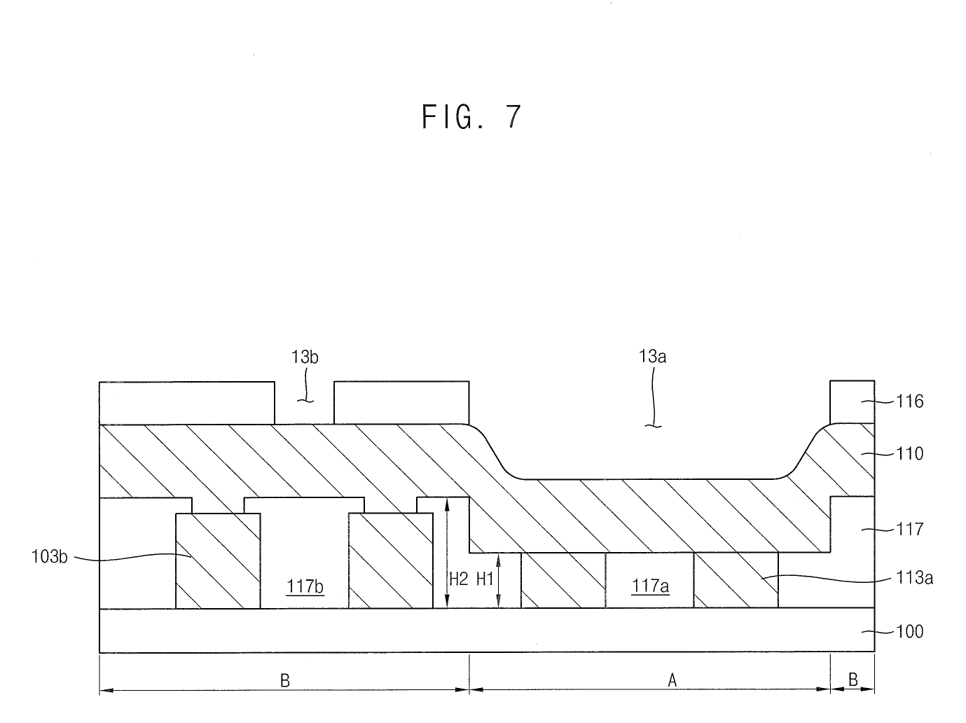

Referring to FIG. 7, a second conductive layer 110 is formed on the preliminary first insulating pattern 117, the first wire pattern 103b and the conductive pattern 113a, which conductive layer 110 fills the opening 12b. The second conductive layer 110 may include a metal, such as aluminum and/or may be a polysilicon doped with impurities.

A third mask pattern 116 is formed on the second conductive layer 110. The third mask pattern 116 has a third hole 13a and a fourth hole 13b. The third hole 13a is over the fuse region A and the fourth hole 13b is over the wire region B. A width of the third hole 13a in the embodiments of FIG. 7 is substantially greater than a width of the fourth hole 13b.

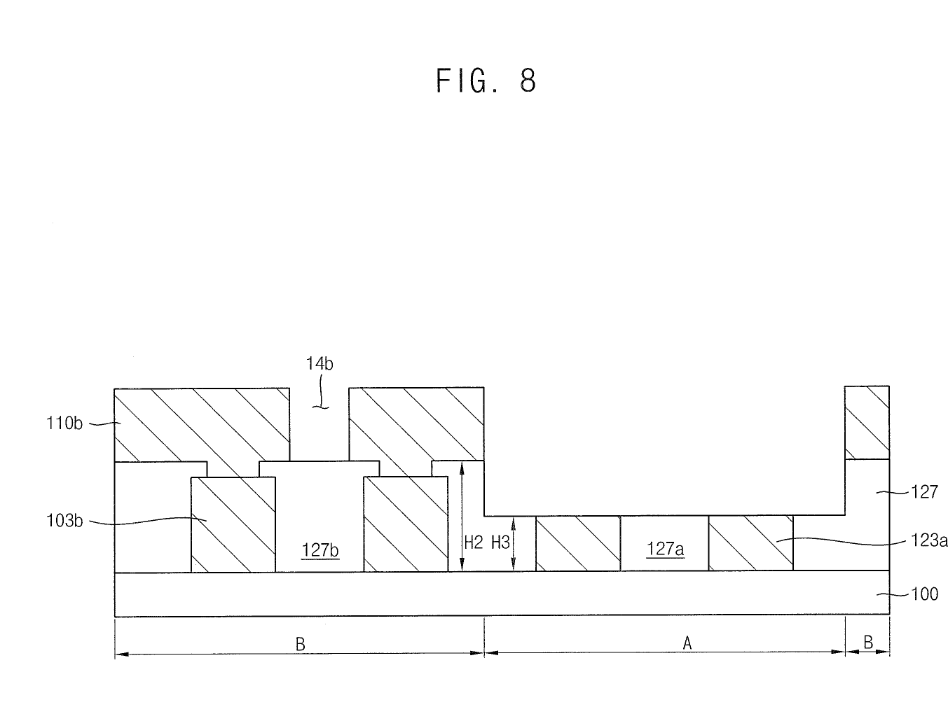

Referring to FIG. 8, a first etching process is performed on the second conductive layer 110, the preliminary first insulating pattern 117 and the conductive pattern 113a using the third mask pattern 116 as an etch mask. The second conductive layer 110, the preliminary first insulating pattern 117 and the conductive pattern 113a are formed into a second wire pattern 110b, a first insulating pattern 127 and a fuse pattern 123a, respectively, by the third etching process. The second wire pattern 110b has a fifth hole 14b partially exposing the first insulating pattern 127.

As described above, the width of the third hole 13a is substantially larger than the width of the fourth hole 13b. Thus, the amount of an etchant provided through the fourth hole 13b may be substantially less than the amount of the etchant provided through the third hole 13a. In addition, the amount of by-product removed through the fourth hole 13b may be substantially less than the amount of by-product removed through the third hole 13a. Thus, an etch rate measured under the fourth hole 13b may be substantially less than an etch rate measured under the third hole 13a.

The conductive pattern 113a is partially removed by the third etching process. Thus, a height of the fuse pattern 123a may be substantially less than that of the conductive pattern 113a. When a ratio of the height of the fuse pattern 123a to the height of the first wire pattern 103b is less than about 1:7, an intensity of a laser beam required to cut the fuse pattern 123a may be relatively large. In addition, the amount of by-product generated when the fuse pattern 123a is cut may be relatively large. On the other hand, when the ratio of the height of the fuse pattern 123a to the height of the first wire pattern 103b is greater than about 1:4, an etching processes required to form the fuse pattern 123a may damage the first insulating pattern 127 excessively. Thus, the ratio of the height of the fuse pattern 123a to the height of the first wire pattern 103b may be about 1:7 to about 1:4. For example, in case that the height of the first wire pattern 103b is about 100 Å, the height of the fuse pattern 123a may be about 40 Å to about 70 Å.

The first insulating pattern 127 may include a first portion 127a and a second portion 127b located on the fuse region A and the wire region B, respectively. The second portion 127b of the first insulating pattern 127 is substantially the same as the second portion 117b of the preliminary first insulating pattern 117. Thus, the second portion 127b of the first insulating pattern 127 may have the second height H2. The first portion 117a of the preliminary first insulating pattern 117 may be partially removed by the third etching process. Thus, the first portion 127a of the first insulating pattern 127 may have a third height H3 substantially less than the first height H1. A thin layer of the portion 127b of the first insulating pattern 127 exposed through the fifth hole 14b may be removed by the third etching process.

The second wire pattern 110b is located on the second portion 127b of the first insulating pattern 127. In addition, the second wire pattern 110b is electrically connected to the first wire pattern 103b. As illustrated in FIG. 8, the second wire pattern 110b may not be formed over the fuse region A.

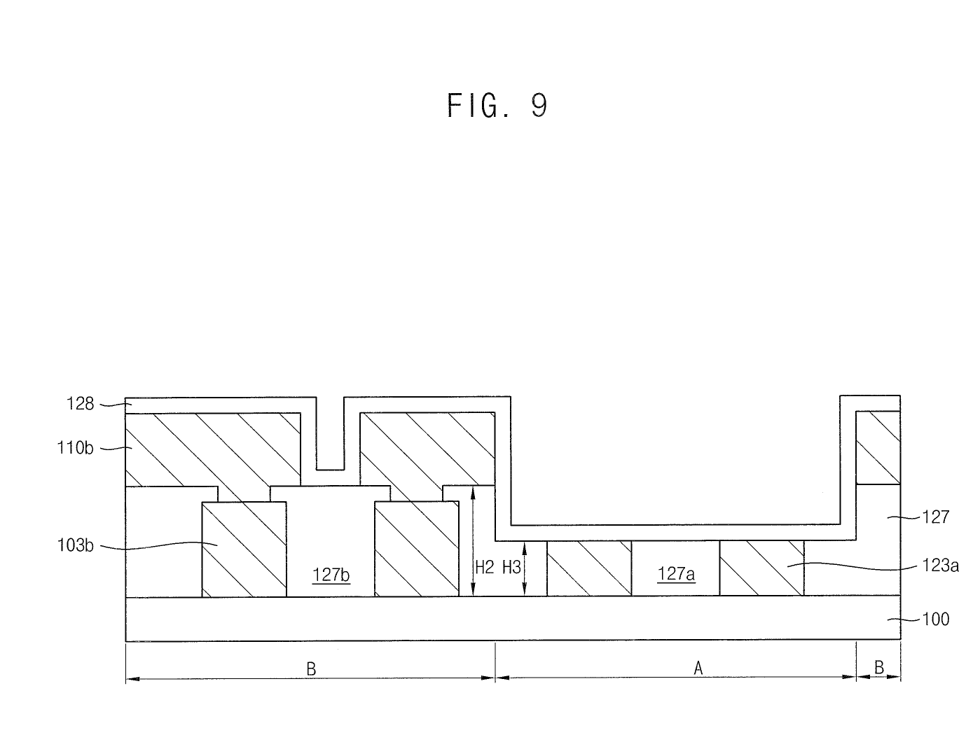

Referring to FIG. 9, a second insulating layer 128 is formed on the second wire pattern 110b, the first insulating pattern 127 and the fuse pattern 123a. The second insulating layer 128 may include an oxide, such as silicon oxide and/or a nitride, such as silicon nitride.

In addition, the second insulating layer 128 may include at least two insulating layers (films). For example, the second insulating layer 128 may include a silicon oxide film and a silicon nitride film formed on the silicon oxide film.

When a ratio of a height of the second insulating layer 128 to the height of the fuse pattern 123a is less than about 3:7, the second insulating layer 128 may not be fully protective and fractures of the fuse pattern 123a may spatter widely when the laser beam cuts the fuse pattern 123a. On the other hand, when the ratio of the height of the second insulating layer 128 to the height of the fuse pattern 123a is greater than about 5:6, the intensity of the laser beam required to cut the fuse pattern 123a may be relatively large. Thus, the ratio of the height of the second insulating layer 128 to the height of the fuse pattern 123a in some embodiments is about 3:7 to about 5:6. As one example, when the height of the fuse pattern 123a is about 70 Å, the height of the second insulating layer 128 may be about 50 Å. As another example, when the height of the fuse pattern 123a is about 70 Å, the height of the second insulating layer 128 may be about 30 Å.

As described above, the second insulating layer 128 may cover the fuse pattern 123a. Thus, the laser beam may stably cut a portion of the fuse pattern 123a. That is, the fractures of the fuse pattern 123a may not spread when the laser beam cuts the portion of the fuse pattern 123a.

In addition, because the second insulating layer 128 covers the fuse pattern 123a, the fractures of the fuse pattern 123a may not be attached to the remaining portion of the fuse pattern 123a. Furthermore, the second insulating layer 128 may cover the fuse pattern 123a and the second wire pattern 110b. Thus, the fractures of the fuse pattern 123a may not be attached to the second wire pattern 110b.

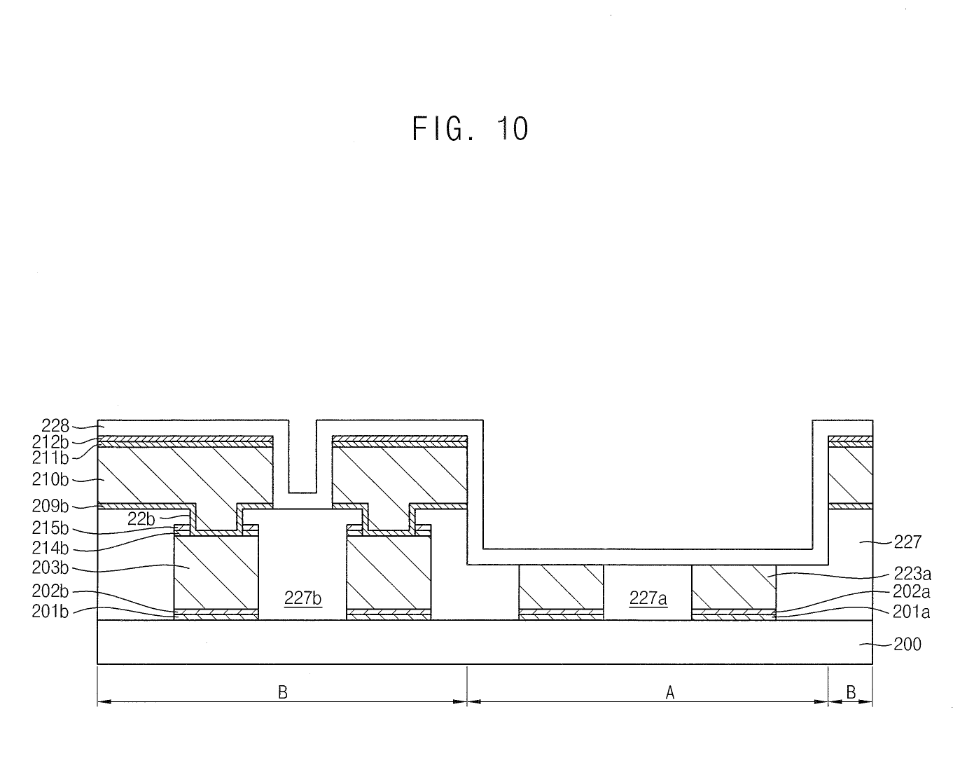

FIG. 10 is a cross-sectional view illustrating a fuse structure according to further embodiments of the present invention. Referring to FIG. 10, a fuse structure 2000 includes an insulating structure 200, a first adhesive fuse pattern 201a, a first capping fuse pattern 202a, a fuse pattern 223a, a first adhesive wire pattern 201b, a second capping wire pattern 202b, a first wire pattern 203b, a second adhesive wire pattern 214b, a second capping wire pattern 215b, a first insulating pattern 227, a third adhesive wire pattern 209b, a second wire pattern 210b, a fourth adhesive wire pattern 211b, a third capping wire pattern 212b and a second insulating layer 228.

The insulating structure 200 includes a fuse region A and a wire region B. The insulating structure 200 may include an oxide, such as silicon oxide and/or a nitride, such as silicon nitride.

Although not illustrated in FIG. 10, a contact electrically connected to a conductive structure located under the insulating structure 200 may be formed through the insulating structure 200. For example, the conductive structure may be a transistor, a capacitor, a wire pattern, a word line, a bit line, a source region and/or a drain region.

The first adhesive fuse pattern 201a, first capping fuse pattern 202a and fuse pattern 203a are formed on a fuse region A of the insulating structure 200. The first adhesive fuse pattern 201a may include a metal, such as titanium. The first capping fuse pattern 202a may include a metal nitride, such as titanium nitride. The fuse pattern 203a may include a metal, such as aluminum and/or a polysilicon doped with impurities.

The first adhesive wire pattern 201b, second capping wire pattern 202b, first wire pattern 203b, second adhesive wire pattern 214b and second capping wire pattern 215b are formed on a wire region B of the insulating structure 200. The first adhesive wire pattern 201b may include a metal, such as titanium. The second capping wire pattern 202b may include a metal nitride, such as titanium nitride. The first wire pattern 203b may include a metal, such as aluminum and/or a polysilicon doped with impurities. The second adhesive wire pattern 214b may include a metal, such as titanium. The second capping wire pattern 215b may include a metal nitride, such as titanium nitride.

A height of the fuse pattern 223a, in the embodiments of FIG. 10, is substantially less than a height of the first wire pattern 203a. When a ratio of the height of the fuse pattern 223a to the height of the first wire pattern 203b is less than about 1:7, an intensity of a laser beam required to cut the fuse pattern 223a may be relatively large. In addition, the amount of by-product generated when the fuse pattern 223a is cut may be relatively large. On the other hand, when the ratio of the height of the fuse pattern 223a to the height of the first wire pattern 203b is greater than about 1:4, etching processes required to form the fuse pattern 223a may damage the first insulating pattern 227 excessively. Thus, the ratio of the height of the fuse pattern 223a to the height of the first wire pattern 203b in some embodiments may be about 1:7 to about 1:4. For example, when the height of the first wire pattern 203b is about 100 Å, the height of the fuse pattern 223a may be about 40 Å to about 70 Å.

The first insulating pattern 227 is formed on the insulating structure 200 and encloses (covers) sidewalls of the first adhesive fuse pattern 201a, the first capping fuse pattern 202a, the fuse pattern 203a, the first adhesive wire pattern 201b, the second capping wire pattern 202b, the first wire pattern 203b, the second adhesive wire pattern 214b and the second capping wire pattern 215b. The first insulating pattern 227 may include an oxide, such as silicon oxide and/or a nitride, such as silicon nitride.

The first insulating pattern 227 may include a first portion 227a and a second portion 227b located on the fuse region A and the wire region B, respectively. In the embodiments of FIG. 10, a height of the first portion 227a is substantially greater than a height of the second portion 227b.

The third adhesive wire pattern 209b is located on the second portion 227b of the first insulating pattern 227. In addition, the third adhesive wire pattern 209b is electrically connected to the first wire pattern 203b, the second adhesive wire pattern 214b and the second capping wire pattern 215b. As illustrated in FIG. 10, the third wire pattern 209b is not formed over the fuse region A. The third adhesive wire pattern 209b may include a metal, such as titanium.

The second wire pattern 210b, fourth adhesive wire pattern 211b and third capping wire pattern 212b may be formed on the third adhesive wire pattern 209b. The second wire pattern 210b may include a metal, such as aluminum and/or a polysilicon doped with impurities. The fourth adhesive wire pattern 211b may include a metal, such as titanium. The third capping wire pattern 212b may include a metal nitride, such as titanium nitride.

The second insulating layer 228 is located on the third capping wire pattern 212b, the fourth adhesive wire pattern 211b, the second wire pattern 210b, the third adhesive wire pattern 209b, the first insulating pattern 227 and the fuse pattern 223a. The second insulating layer 228 may include an oxide, such as silicon oxide and/or a nitride, such as silicon nitride.

The second insulating layer 228 may include at least two insulating films (layers). For example, the second insulating layer 228 may include a silicon oxide film and a silicon nitride film formed on the silicon oxide film.

When a ratio of a height of the second insulating layer 228 to the height of the fuse pattern 223a is less than about 3:7, the second insulating layer 228 may not be fully protective and fractures of the fuse pattern 223a may spatter widely when the laser beam cuts the fuse pattern 223a. On the other hand, when the ratio of the height of the second insulating layer 228 to the height of the fuse pattern 223a is greater than about 5:6, the intensity of the laser beam required to cut the fuse pattern 223a may be relatively large. Thus, in some embodiments, the ratio of the height of the second insulating layer 228 to the height of the fuse pattern 223a is about 3:7 to about 5:6. As one example, when the height of the fuse pattern 223a is about 60 Å, the height of the second insulating layer 228 may be about 50 Å. As another example, when the height of the fuse pattern 223a is about 70 Å, the height of the second insulating layer 228 may be about 30 Å.

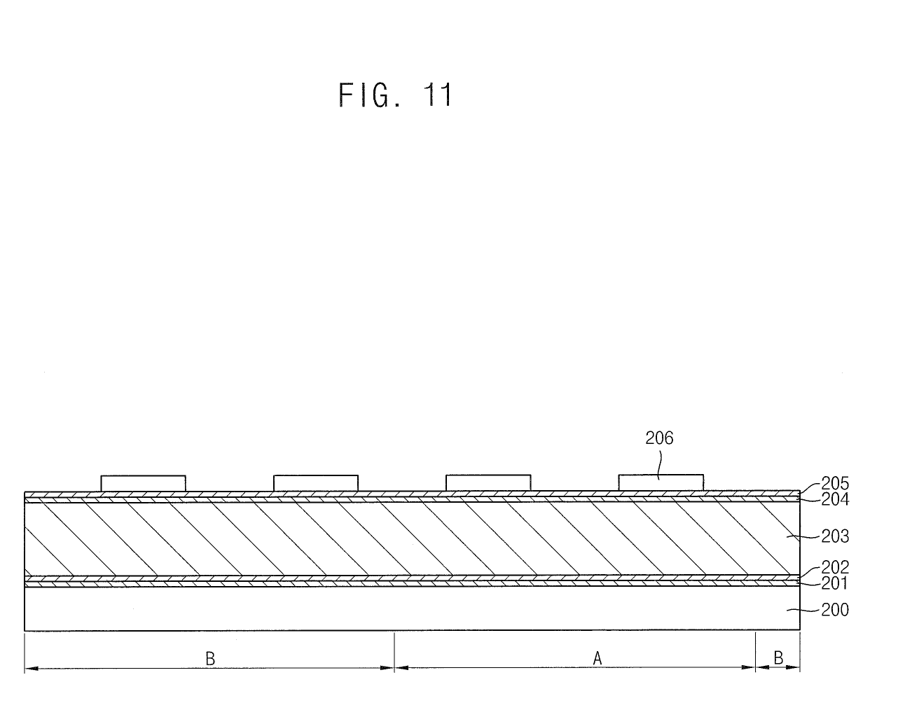

Hereinafter, a method of manufacturing the fuse structure in FIG. 10 according to some embodiments will be described with reference to FIGS. 11 to 17. FIGS. 11 to 17 are cross-sectional views illustrating a method of manufacturing the fuse structure in FIG. 10.

Referring to FIG. 11, an insulating structure 200 having a fuse region A and a wire region B is formed. The insulating structure 200 may include an oxide, such as silicon oxide and/or a nitride, such as silicon nitride.

Although not illustrated in FIG. 11, a contact electrically connected to a conductive structure located under the insulating structure 200 may be formed through the insulating structure 200. For example, the conductive structure may be a transistor, a capacitor, a wire pattern, a word line, a bit line, a source region and/or a drain region.

A first adhesive layer 201, a first capping layer 202, a first conductive layer 203, a second adhesive layer 204 and a second capping layer 205 are formed on the insulating structure 200. The first adhesive layer 201 and the second adhesive layer 204 may include a metal, such as titanium. The first capping layer 202 and the second capping layer 205 may include a metal nitride, such as titanium nitride. The first conductive layer 203 may include a metal, such as aluminum and/or polysilicon doped with impurities.

A first mask pattern 206 is formed on the first conductive layer 203. The first mask pattern 206 may have an etching selectivity with respect to the second capping layer 205, the second adhesive layer 204, the first conductive layer 203, the first capping layer 202 and the first adhesive layer 201. That is, the first mask pattern 205 may be substantially not etched when the second capping layer 205, the second adhesive layer 204, the first conductive layer 203, the first capping layer 202 and the first adhesive layer 201 are etched. The first mask pattern 206 may include a nitride, such as silicon nitride and/or an oxide, such as silicon oxide.

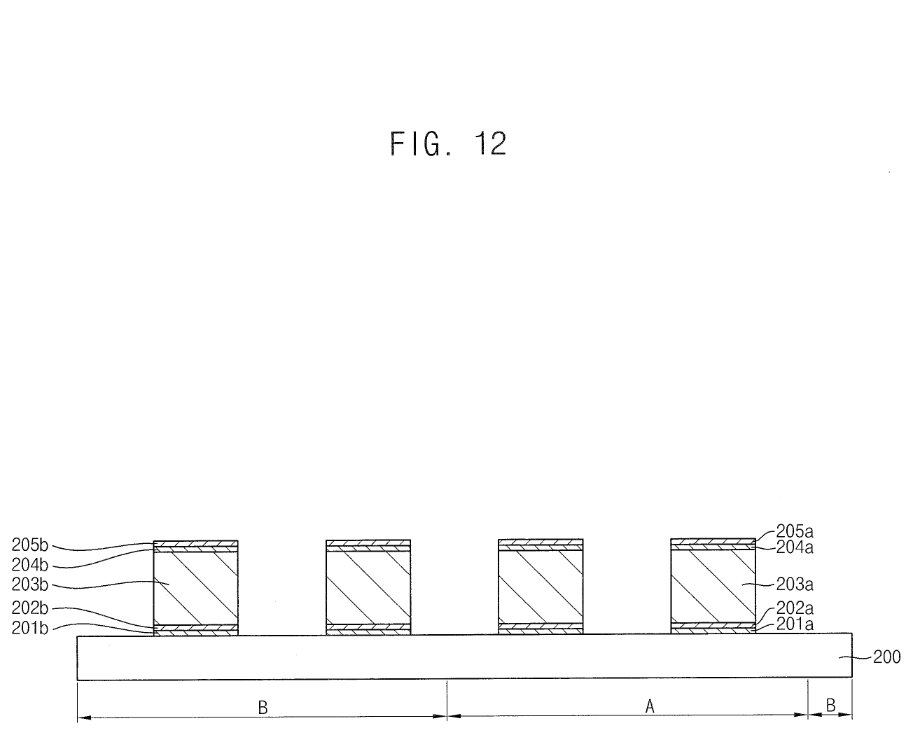

Referring to FIG. 12, a first etching process is performed on the second capping layer 205, the second adhesive layer 204, the first conductive layer 203, the first capping layer 202 and the first adhesive layer 201 using the first mask pattern 206 as an etch mask.

The first adhesive layer 201 may be formed into a first adhesive fuse pattern 201a and a first adhesive wire pattern 201b by the first etching process. The first adhesive fuse pattern 201a and the first adhesive wire pattern 201b may be formed on the fuse region A and the wire region B, respectively.

The first capping layer 202 may be formed into the first capping fuse pattern 202a and the first capping wire pattern 202b by the first etching process. The first capping fuse pattern 202a and the first capping wire pattern 202b may be formed on the first adhesive fuse pattern 201a and the first adhesive wire pattern 201b, respectively.

The first conductive layer 203 is formed into a preliminary conductive pattern 203a and a first wire pattern 203b by the first etching process. The preliminary conductive pattern 203a and the first wire pattern 203b are formed on the first capping fuse pattern 202a and the first capping wire pattern 202b, respectively.

The second adhesive layer 204 is formed into a second adhesive fuse pattern 204a and a preliminary second adhesive wire pattern 204b by the first etching process. The second adhesive fuse pattern 204a and the preliminary second adhesive wire pattern 204b are formed on the preliminary conductive pattern 203a and the first wire pattern 203b, respectively.

The second capping layer 205 is formed into a second capping fuse pattern 205a and a preliminary second capping wire pattern 205b by the first etching process. The second capping fuse pattern 205a and the preliminary second capping wire pattern 205b are formed on the second adhesive fuse pattern 204a and the preliminary second adhesive wire pattern 204b, respectively.

Thereafter, the first mask pattern 206 is removed. The first mask pattern 206 may be removed, for example, by an ashing process and/or a strip process. In other words, these processes may be used alone or in combination.

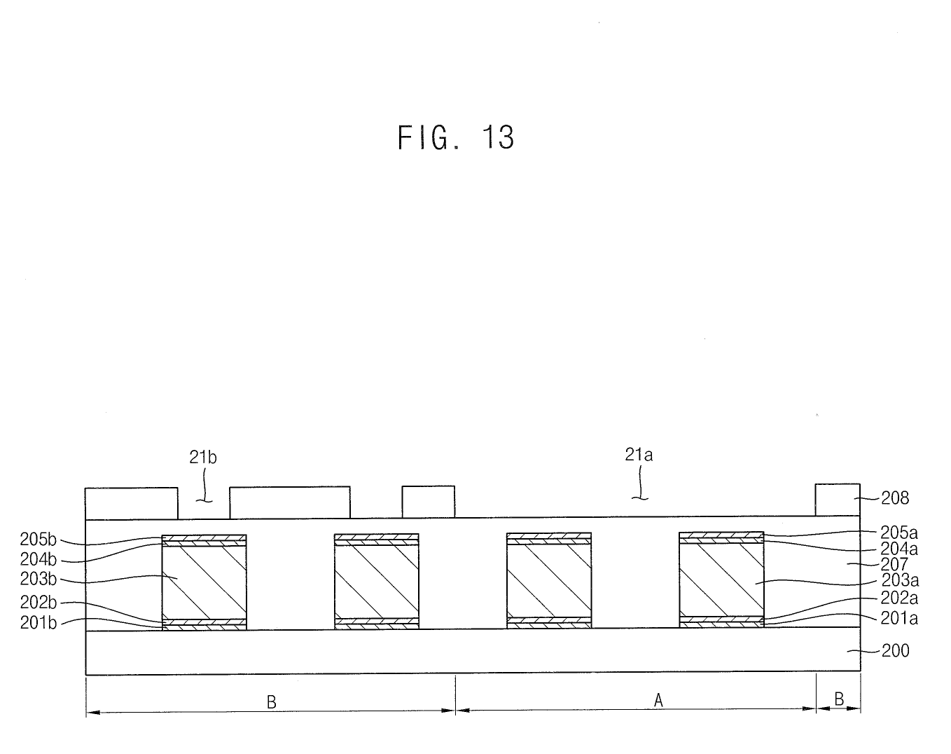

Referring to FIG. 13, a first insulating layer 207 is formed on the insulating structure 200 to cover the first adhesive fuse pattern 201a, the first adhesive wire pattern 201b, the first capping fuse pattern 202a, the first capping wire pattern 202b, the preliminary conductive pattern 203a, the first wire pattern 203b, the second adhesive fuse pattern 204a, the preliminary second adhesive wire pattern 204b, the preliminary second capping fuse pattern 205a and the second capping wire pattern 205b. The first insulating layer 207 may include an oxide, such as silicon oxide and/or a nitride, such as silicon nitride.

A second mask pattern 208 is formed on the first insulating layer 207. The second mask pattern 208 has a first hole 21a and a second hole 21b. The first hole 21a corresponds to the fuse region A. The second hole 21b corresponds to the preliminary second capping wire pattern 205b located on the wire region B. A width of the first hole 21a in the illustrated embodiments is substantially greater than a width of the second hole 21b.

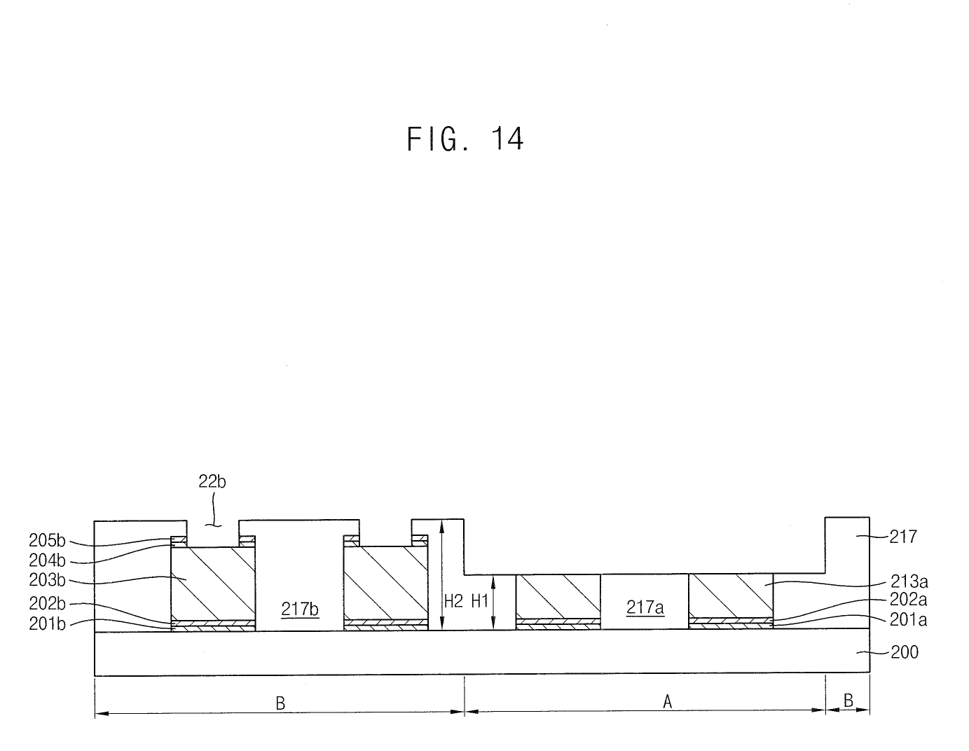

Referring to FIG. 14, a second etching process is performed on the first insulating layer 207, the second capping fuse pattern 205a, the second adhesive fuse pattern 204a, the preliminary conductive pattern 203a, the preliminary second capping wire pattern 205b and the preliminary second capping wire pattern 204b using the second mask pattern 208 as an etch mask.

As described above, the width of the first hole 21a is substantially larger than the width of the second hole 21b. Thus, the amount of an etchant provided through the first hole 21a may be substantially larger than the amount of the etchant provided through the second hole 21b. In addition, the amount of by-product removed through the first hole 21a may be substantially larger than the amount of by-product removed through the second hole 21b. Thus, an etch rate measured under the first hole 21a may be substantially larger than an etch rate measured under the second hole 21b.

The first insulating layer 207 is formed into a preliminary first insulating pattern 217 by the second etching process. The preliminary first insulating pattern 217 may include a first portion 217a and a second portion 217b located on the fuse region A and the wire region B, respectively. The first portion 217a and the second portion 217b may have a first height H1 and a second height H2, respectively. In the embodiments of FIG. 14, the first height H1 is substantially less than the second height H2.

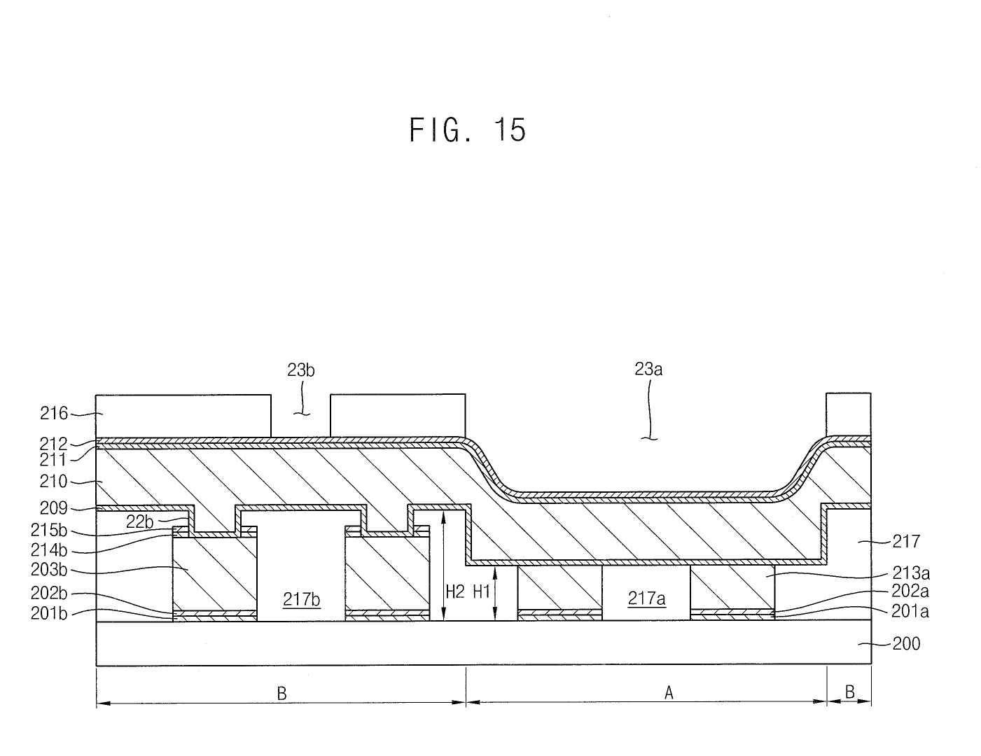

The second capping fuse pattern 205a and the second adhesive fuse pattern 204a are removed by the second etching process. The preliminary second capping wire pattern 205b and the preliminary second adhesive wire pattern 204b are formed into a second capping wire pattern 215b and a second adhesive wire pattern 214b (FIG. 15), respectively, by the second etching process.

The second adhesive wire pattern 214b, the second capping wire pattern 215b and the second portion of the preliminary first insulating pattern 217 may share the opening 22b. The opening 22b may partially expose the first wire pattern 203b. A thin layer of a portion of the first wire pattern 203b exposed through the opening 22b may be removed by the second etching process.

The preliminary conductive pattern 203a may be formed into a conductive pattern 213a having a height substantially less than a height of the preliminary conductive pattern 203a by the second etching process. The first portion 217a of the preliminary first insulating pattern 217 may enclose (cover) a sidewall of the conductive pattern 213a. Thus, an upper face of the conductive pattern 213a may be exposed.

Referring to FIG. 15, the third adhesive layer 209, the second conductive layer 210, the fourth adhesive layer 211 and the third capping layer 212 are formed on the preliminary first insulating pattern 217, the second capping wire pattern 215b, the second adhesive wire pattern 214b, the first wire pattern 203b and the conductive pattern 213a.

The third adhesive layer 209 may include a metal, such as titanium. The second conductive layer 210 may include a metal, such as aluminum and/or polysilicon doped with impurities. The fourth adhesive layer 211 may include a metal, such as titanium. The third capping layer 212 may include a metal nitride, such as titanium nitride.

A third mask pattern 216 is formed on the third capping layer 212. The third mask pattern 216 has a third hole 23a and a fourth hole 23b. The third hole 23a corresponds to the fuse region A. The fourth hole 23b is located over the wire region B. In the embodiments of FIG. 15, the width of the third hole 23a is substantially greater than the width of the fourth hole 23b.

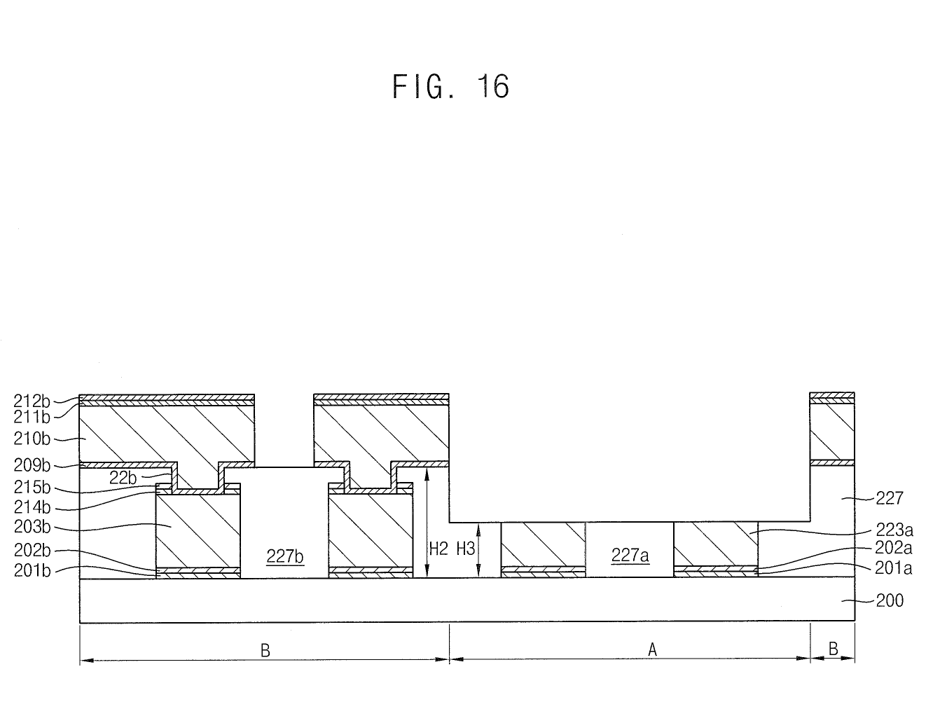

Referring to FIG. 16, a third etching process is performed on the third capping layer 212, the fourth adhesive layer 211, the second conductive layer 210, the third adhesive layer 209, the preliminary first insulating pattern 217 and the conductive pattern 213a using the third mask pattern 216 as an etch mask. The third capping layer 212, the fourth adhesive layer 211, the second conductive layer 210, the third adhesive layer 209, the preliminary first insulating pattern 217 and the conductive pattern 213a are formed into a third capping wire pattern 212b, a fourth adhesive wire pattern 211b, a second wire pattern 210b, a third adhesive wire pattern 209b, a first insulating pattern 227 and a fuse pattern 223a, respectively.

As described above, the width of the third hole 23a is substantially greater than the width of the fourth hole 23b. Thus, the amount of an etchant provided through the fourth hole 23b may be substantially less than the amount of the etchant provided through the third hole 23a. In addition, the amount of by-product removed through the fourth hole 23b may be substantially less than the amount of by-product removed through the third hole 23a. Thus, an etch rate measured under the fourth hole 23b may be substantially less than an etch rate measured under the third hole 23a.

The conductive pattern 213a is partially removed by the third etching process. Thus, a height of the fuse pattern 223a may be substantially less than that of the conductive pattern 213a. When a ratio of the height of the fuse pattern 223a to the height of the first wire pattern 203b is less than about 1:7, an intensity of a laser beam required to cut the fuse pattern 223a may be relatively great. In addition, the amount of by-product generated when the fuse pattern 223a is cut may be relatively great. On the other hand, when the ratio of the height of the fuse pattern 223a to the height of the first wire pattern 203b is greater than about 1:4, the etching processes required to form the fuse pattern 223a may damage the first insulating pattern 227 excessively. Thus, in some embodiments, the ratio of the height of the fuse pattern 223a to the height of the first wire pattern 203b may be about 1:7 to about 1:4. For example, when the height of the first wire pattern 203b is about 100 Å, the height of the fuse pattern 223a may be about 40 Å to about 70 Å.

The first insulating pattern 227 includes a first portion 227a and a second portion 227b located on the fuse region A and the wire region B, respectively. The second portion 227b of the first insulating pattern 227 is substantially the same as the second portion 217b of the preliminary first insulating pattern 217. Thus, the second portion 227b of the first insulating pattern 227 may have the second height. The first portion 217a of the preliminary first insulating pattern 217 is partially removed by the third etching process. Thus, the first portion 227a of the first insulating pattern 227 may have a third height H3 substantially less than the first height H1.

The third adhesive wire pattern 209b is located on the second portion 227b of the first insulating pattern 227. The third adhesive wire pattern 209b is electrically connected to the first wire pattern 203b, the second adhesive wire pattern 214b and the second capping wire pattern 215b. The second wire pattern 210b is located on the third adhesive wire pattern 209b. The fourth adhesive wire pattern 211b is located on the second wire pattern 210b. The third capping wire pattern 212b is located on the fourth adhesive wire pattern 211b.

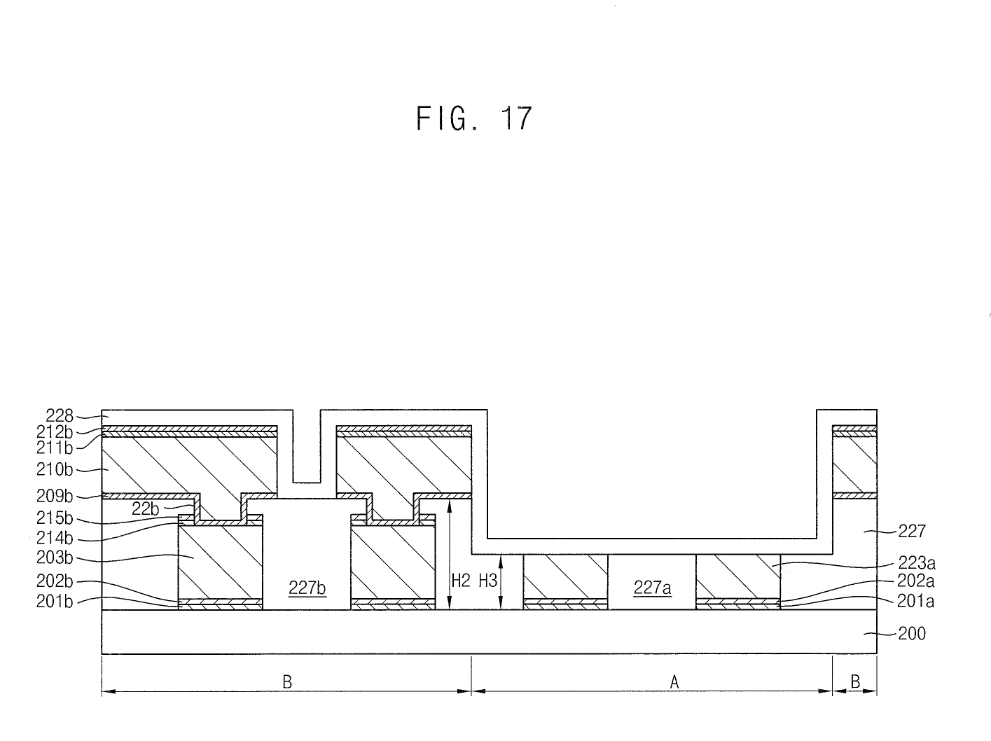

Referring to FIG. 17, a second insulating layer 228 is formed on the third capping wire pattern 212b, the fourth adhesive wire pattern 211b, the second wire pattern 210b, the first insulating pattern 227 and the fuse pattern 223a. The second insulating layer 228 may include an oxide, such as silicon oxide and/or a nitride, such as silicon nitride. The second insulating layer 228 may include at least two insulating films (layers). For example, the second insulating layer 228 may include a silicon oxide film and a silicon nitride film formed on the silicon oxide film.

When a ratio of a height of the second insulating layer 228 to the height of the fuse pattern 223a is less than about 3:7, the second insulating layer 228 may not be fully protective and fractures of the fuse pattern 223a may spatter widely when the fuse pattern 223a is cut by the laser beam. On the other hand, when the ratio of the height of the second insulating layer 228 to the height of the fuse pattern 223a is greater than about 5:6, the intensity of the laser beam required to cut the fuse pattern 223a may be relatively great. Thus, in some embodiments, the ratio of the height of the second insulating layer 228 to the height of the fuse pattern 223a is about 3:7 to about 5:6. As one example, when the height of the fuse pattern 223a is about 70 Å, the height of the second insulating layer 228 may be about 50 Å. As another example, when the height of the fuse pattern 223a is about 70 Å, the height of the second insulating layer 228 may be about 30 Å.

As described above, the second insulating layer 228 may cover the fuse pattern 223a. Thus, a portion of the fuse pattern 223a may be stably cut by the laser beam. That is, the fractures of the fuse pattern 223a may not spread when the portion of the fuse pattern 223a is cut by the laser beam.

In addition, because the second insulating layer 228 covers the fuse pattern 223a, the fractures of the fuse pattern 223a may not be attached to the remaining portion of the fuse pattern 223a. Furthermore, the second insulating layer 228 may cover the fuse pattern 223a and the second wire pattern 210b. Thus, the fractures of the fuse pattern 223a may not be attached to the second wire pattern 210b.

According to some embodiments of the present invention, an insulating layer may cover a fuse pattern. Thus, a portion of the fuse pattern may be stably cut by a laser beam. That is, the fractures of the fuse pattern may not spread when the portion of the fuse pattern is cut by the laser beam.

In addition, because the insulating layer covers the fuse pattern, the fractures of the fuse pattern may not be attached to the remaining portion of the fuse pattern. Furthermore, the insulating layer may cover the fuse pattern and a wire pattern adjacent to the fuse pattern. Thus, the fractures of the fuse pattern may not be attached to the wire pattern.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A fuse structure comprising:
an insulating structure having a fuse region and a wire region proximate the fuse region;
a fuse pattern on the fuse region;
an insulating pattern having a first portion and a second portion, the first portion being located on the fuse region and covering a sidewall of the fuse pattern, the second portion being located on the wire region; and
an insulating layer on the insulating pattern and the fuse pattern and having a height selected to limit spread of fractures of the fuse pattern generated by cutting of the fuse pattern.

2. The fuse structure of claim 1, further comprising:
a first wire pattern on the wire region, the first wire pattern having a sidewall covered by the second portion; and
a second wire pattern on the second portion that is electrically connected to the first wire pattern;
wherein the insulating layer is on exposed surfaces of the insulating pattern, the fuse pattern and the second wire pattern.

3. The fuse structure of claim 2, wherein a height of the first portion is less than a height of the second portion.

4. The fuse structure of claim 2, wherein a height of the fuse pattern is less than a height of the first wire pattern.

5. The fuse structure of claim 4, wherein a ratio of the height of the fuse pattern to the height of the first wire pattern is about 1:7 to about 1:4.

6. The fuse structure of claim 4, wherein the insulating layer includes silicon oxide and wherein the fuse pattern includes aluminum.

7. The fuse structure of claim 4, wherein a ratio of the height of the insulating layer to the height of the fuse pattern is about 3:7 to about 5:6.

8. The fuse structure of claim 1, wherein the insulating layer includes at least two insulating films.

9. A method of forming a fuse structure, the method comprising:
forming a preliminary conductive pattern on an insulating structure;
forming a first insulating layer on the insulating structure and covering the preliminary conductive pattern;
reducing heights of the first insulating layer and the preliminary conductive pattern to form a fuse pattern and a first insulating pattern, wherein a sidewall of the fuse pattern is covered by the first insulating pattern; and then
forming a second insulating layer on the first insulating pattern and the fuse pattern, the further insulating layer being formed to a height selected to limit spread of fractures of the fuse pattern generated by cutting of the fuse pattern.

10. The method of claim 9, wherein reducing heights of the first insulating layer and the preliminary conductive pattern includes:
etching the first insulating layer and the preliminary conductive pattern to form a preliminary first insulating pattern and a conductive pattern, the preliminary first insulating pattern having a height less than a height of the first insulating layer, the conductive pattern having a height less than the height of the preliminary conductive pattern, the conductive pattern having a sidewall covered by the preliminary first insulating pattern;
forming a conductive layer on the preliminary first insulating pattern and the conductive pattern; and
etching the conductive layer, the preliminary first insulating pattern and the conductive pattern to form the first insulating pattern and the fuse pattern, the first insulating pattern having a height less than the height of the preliminary pattern, the fuse pattern having a height less than the height of the conductive pattern, the fuse pattern having a sidewall covered by the first insulating pattern.

11. The method of claim 9, wherein reducing heights of the first insulating layer and the preliminary conductive pattern includes reducing heights of the first insulating layer and the preliminary conductive pattern to provide a ratio of the height of the fuse pattern to the height of the first wire pattern of about 1:7 to about 1:4.

12. The method of claim 9, wherein the preliminary conductive pattern includes aluminum and the insulating layer includes silicon oxide.

13. The method of claim 9, wherein forming the second insulating layer includes forming the height of the insulating layer to provide a ratio of the height of the insulating layer to the height of the fuse pattern of about 3:7 to about 5:6.

14. The method of claim 9, wherein forming the second insulating layer includes forming a first insulating film and forming a second insulating film on the first insulating film.

15. The method of claim 14, wherein the first insulating film comprises a silicon oxide film and the second insulating film comprises a silicon nitride film.

16. The method of claim 9, wherein forming a preliminary conductive pattern includes:
forming a first adhesive layer;
forming a first capping layer on the first adhesive layer;
forming a conductive layer on the first capping layer;
forming a second adhesive layer on the conductive layer;
forming a second capping layer on the second adhesive layer;
forming a mask pattern on the second capping layer; and
etching the first adhesive layer, the first capping layer, the conductive layer on the first capping layer, the second adhesive layer and the second capping layer using the mask pattern to form the preliminary conductive pattern.

17. The method of claim 16, wherein the first and second adhesive layers include a metal and wherein the first and second capping layers include a metal nitride.

18. A method of forming a fuse structure, the method comprising:
providing an insulating structure including a wire region and a fuse region;
forming a first wire pattern on the wire region;
forming a preliminary conductive pattern on the fuse region;
forming a first insulating layer on the insulating structure that covers the first wire pattern and the preliminary conductive pattern;
etching the first insulating layer and the preliminary conductive pattern to form a preliminary first insulating pattern and a conductive pattern, the preliminary first insulating pattern having an opening exposing a portion of the first wire pattern, the preliminary first insulating pattern including a first portion located on the wire region and a second portion located on the fuse region, the second portion having a height less than a height of the first portion, the conductive pattern having a height less than a height of the preliminary conductive pattern;
forming a conductive layer on the preliminary first insulating pattern, the first wire pattern and the conductive pattern, the conductive layer filling the opening exposing the portion of the first wire pattern;
etching the conductive layer, the preliminary conductive pattern and the preliminary first insulating pattern to form a second wire pattern, a fuse pattern and a first insulating pattern, the second wire pattern being located on the second portion and electrically connected to the first wire pattern, the fuse pattern having a height less than a height of the preliminary conductive pattern, a portion of the first insulating pattern located on the fuse region having a height less than the height of the first portion; and then
forming an insulating layer on the etched conductive layer, the preliminary conductive pattern and the preliminary first insulating pattern to a height selected to limit spread of fractures of the fuse pattern generated by cutting of the fuse pattern.

19. The method of claim 18, wherein etching the first insulating layer is preceded by forming a mask pattern on the first insulating layer, the mask pattern including a first opening on the fuse region and a second opening on the wire region, the first opening having a width greater than a width of the second opening to provide a greater etch rate in the fuse region than the wire region and wherein etching the first insulating layer comprises etching the first insulating layer and the preliminary conductive pattern using the mask pattern.

20. The method of claim 18, wherein a ratio of the height of the fuse pattern to the height of the first wire pattern is about 1:7 to about 1:4.

21. The method of claim 18, wherein forming the insulating layer includes forming the insulating layer to provide a ratio of the height of the insulating layer to the height of the fuse pattern of about 3:7 to about 5:6.
